(19) United States
(12) Patent Application Publication
(10) Pub. No.: US 2025/0293177 A1
(43) Pub. Date: Sep. 18, 2025

(54) SYSTEMS AND METHODS FOR COMPONENT ISOLATION

(71) Applicant: Qorvo US, Inc., Greensboro, NC (US)

(72) Inventors: Loizos Loizou, Grasbrunn (DE); Vladimir Kolchuzhin, Hohenschaeftlarn (DE)

(21) Appl. No.: 19/064,977

(22) Filed: Feb. 27, 2025

Related U.S. Application Data
(60) Provisional application No. 63/564,252, filed on Mar. 12, 2024.
(60) Provisional application No. 63/641,489, filed on May 2, 2024.

(51) Int. Cl. H01L 23/552; H01L 21/56; H01L 23/31; H01L 23/538; H01L 25/07

(52) U.S. Cl. CPC H01L 23/552; H01L 21/56; H01L 23/5383; H01L 25/072; H01L 23/3121

(57) ABSTRACT

Systems and methods for component isolation are disclosed. In one aspect, a “top” absorbing wall or layer may be formed from ferromagnetic or other absorbing material. This isolation wall may be positioned above components such as for example, filters (acoustic or otherwise), surface-mounted devices (SMDs), amplifiers (e.g., power amplifiers and low noise amplifiers), switches, or the like. The absorbing isolation layer may be introduced as part of an overmold package (or undermold (e.g., double-sided ball grid array (DSBGA)) and may be thinner than conventional Faraday cages or shields, allowing components to be placed in closer proximity without increasing crosstalk or electromagnetic interference (EMI). The absorbing wall may be used alone or in conjunction with a shield. Where a shield is used, the absorbing wall may help improve isolation and reduce leakage current that might otherwise appear on the shield.

### PRIORITY APPLICATIONS

The present application claims priority to U.S. Provisional Patent Application Ser. No. 63/564,252, entitled SYSTEMS AND METHODS FOR COMPONENT ISOLATION, filed on Mar. 12, 2024, the contents of which is hereby incorporated by reference in its entirety.

The present application claims priority to U.S. Provisional Patent Application Ser. No. 63/641,489, entitled SYSTEMS AND METHODS FOR COMPONENT ISOLATION, filed on May 2, 2024, the contents of which is hereby incorporated by reference in its entirety.

### BACKGROUND

### I. Field of the Disclosure

The technology of the disclosure relates generally to component packages and is particularly well suited for radio frequency (RF) component packages and modules.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. Concurrent with this increased functionality is a perceived pressure to continue to decrease component size within the mobile communication device. This trend is not unique to mobile communication devices and is present in other devices as well. The general trend is to have more dense and compact printed circuit boards, which results in components being placed near one another. Where transmitter and receiver components are in close proximity, there may be unwanted crosstalk or other electromagnetic interference (EMI), particularly at radio frequencies. Providing isolation in such cramped quarters provides room for innovation.

### SUMMARY

Aspects disclosed in the detailed description include systems and methods for component isolation. In particular, aspects of the present disclosure contemplate using a “top” absorbing wall or layer that may be formed from ferromagnetic or other absorbing material. This isolation wall may be positioned above components such as, for example, filters (acoustic or otherwise), surface-mounted devices (SMDs), amplifiers (e.g., power amplifiers and low noise amplifiers), switches, or the like. The absorbing isolation layer may be introduced as part of an overmold package (or undermold (e.g., double-sided ball grid array (DSBGA) or double sided molded ball grid array (DSMBGA)) and may be thinner than conventional Faraday cages or shields, allowing components to be placed in closer proximity without increasing crosstalk or electromagnetic interference (EMI). The absorbing wall may be used alone or in conjunction with a shield. Where a shield is used, the absorbing wall may help improve isolation and reduce leakage current that might otherwise appear on the shield. While particularly useful for radio frequencies, it should be appreciated that the teachings may have broader application.

In this regard, in one aspect, a package is disclosed. The package includes a laminate and a first component positioned on the laminate. The package also includes a conductive shield and at least one absorbing layer positioned between the first component and the conductive shield.

In another aspect, a communication device is disclosed. The communication device includes a transceiver chain comprising a package. The package includes a laminate and a first component positioned on the laminate. The package also includes a conductive shield and at least one absorbing layer positioned between the first component and the conductive shield.

In another aspect, a method of forming a package is disclosed. The method includes placing a component on a laminate and placing mold material over the component. The method also includes placing an absorbing layer over the overmold material and placing a conductive shield over the absorbing layer.

In another aspect, a package is disclosed. The package includes a laminate and a first component positioned on a first side of the laminate, wherein the laminate comprises a second side opposite the first side and at least one absorbing layer positioned in an undermold on the second side laminate.

### BRIEF DESCRIPTION OF THE DRAWINGS

FIG. 1A is a front perspective view of a pair of components mounted on a printed circuit board (PCB) without any isolation;

FIG. 1B is a front elevational view of the pair of components of FIG. 1A;

FIG. 1C is a top-plan view of the pair of components of FIG. 1A;

FIG. 2A is a front perspective view of a pair of components with an absorbing isolation wall placed therebetween according to exemplary aspects of the present disclosure;

FIG. 2B is a front elevational view of the pair of components of FIG. 2A;

FIG. 2C is a top-plan view of the pair of components of FIG. 2A;

FIG. 3A is a front elevational view of a pair of components with respective absorbing isolation boxes placed therearound according to exemplary aspects of the present disclosure;

FIG. 3B is a front elevational view of the pair of components of FIG. 3A;

FIG. 3C is a top-plan view of the pair of components of FIG. 3A;

FIGS. 4-9 are top-plan views of a variety of absorbing isolation wall configurations that may be used by exemplary aspects of the present disclosure;

FIG. 10 is a flowchart illustrating a process for forming isolated components;

FIGS. 11A-11F represent side elevation views of a work product as it undergoes the forming of the process of FIG. 10;

FIG. 12A is a cross-sectional side elevation view of a package with an absorbing layer parallel to and above a laminate but below a conductive shield;

FIG. 12B is a front isometric view of the package of FIG. 12A;

FIG. 13A is a top-down plan view of a laminate with components thereon;

FIGS. 13B-13D are isometric views of the laminate of FIG. 13A included in a package with a partial absorbing layer covering different features of the laminate;

FIG. 14 is a flowchart illustrating a process for forming a package with absorbing elements according to aspects of the present disclosure;

FIG. 15 is a block diagram of a mobile terminal, which, according to the present disclosure, may include the isolation techniques of FIGS. 2A-9, 12A-13D, or 16; and

FIG. 16 is a side cross-sectional view of a double-sided package with isolating walls on both sides of the package.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figure, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively. Aspects of the present disclosure are well suited for use in the front-end module that contains the power amplifiers as the issues being resolved are more pronounced under large signal conditions such as exist after the power amplifier.

Aspects disclosed in the detailed description include systems and methods for component isolation. In particular, aspects of the present disclosure contemplate using a “top” absorbing wall or layer that may be formed from ferromagnetic or other absorbing material. This isolation wall may be positioned above components such as, for example, filters (acoustic or otherwise), surface-mounted devices (SMDs), amplifiers (e.g., power amplifiers and low noise amplifiers), switches, or the like. The absorbing isolation layer may be introduced as part of an overmold package (or undermold (e.g., double-sided ball grid array (DSBGA) or double-sided molded ball grid array (DSMBGA)) and may be thinner than conventional Faraday cages or shields, allowing components to be placed in closer proximity without increasing crosstalk or electromagnetic interference (EMI). The absorbing wall may be used alone or in conjunction with a shield. Where a shield is used, the absorbing wall may help improve isolation and reduce leakage current that might otherwise appear on the shield. Further, use of the absorbing material can reduce or eliminate the need for conventional shielding using vertical walls or wire-bonds, which are costly and require substantial real estate within the device. While particularly useful for radio frequencies, it should be appreciated that the teachings may have broader application.

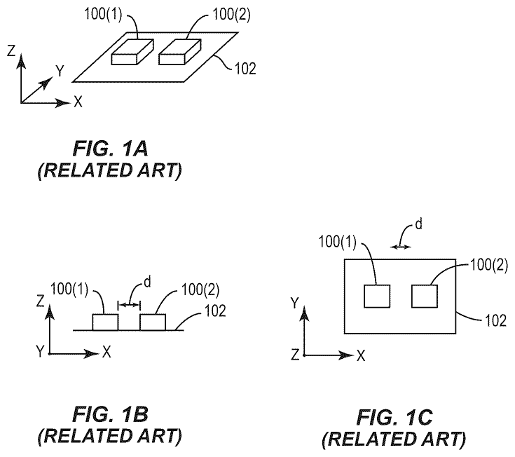

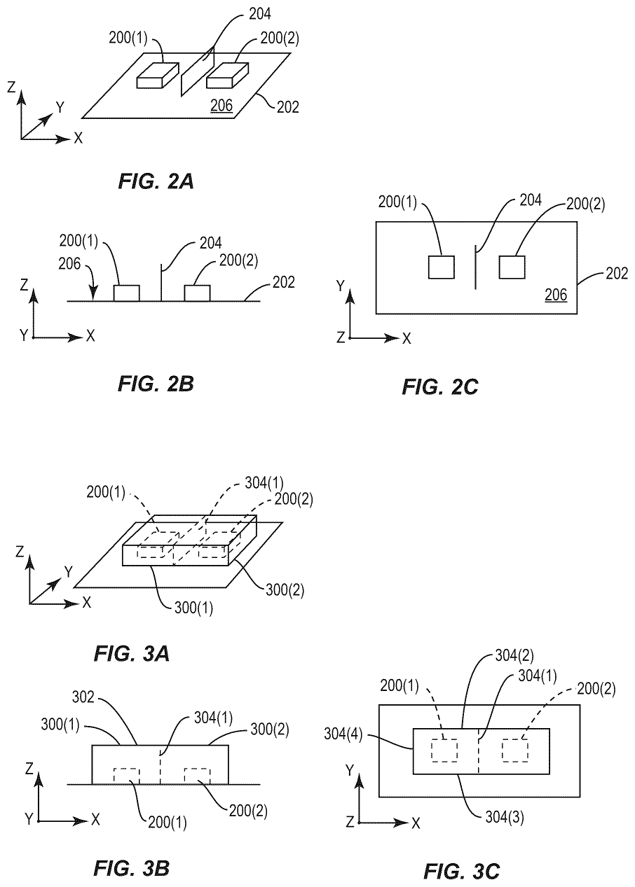

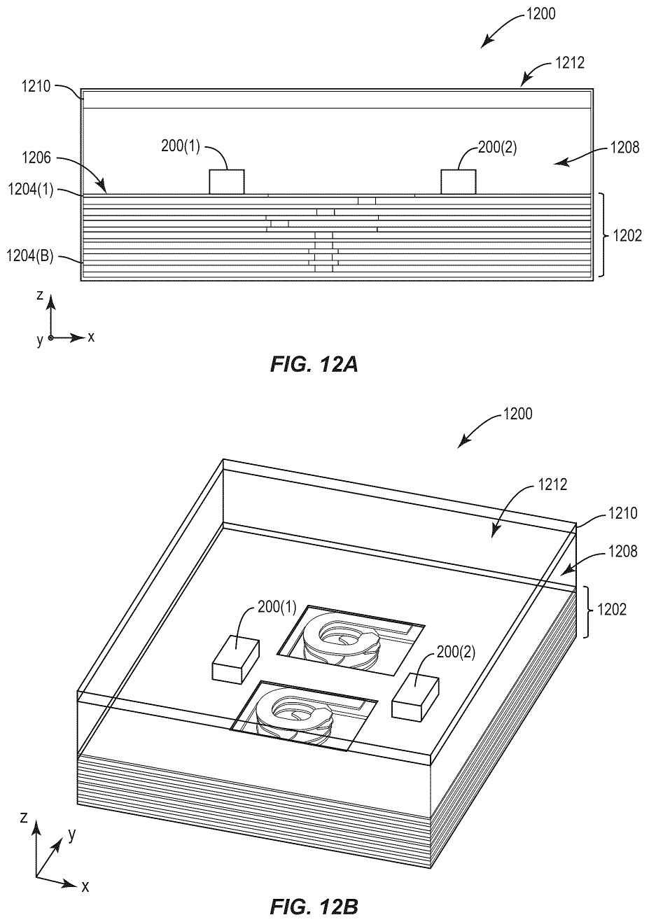

Before addressing particular aspects of the present disclosure, a discussion of a package that may benefit from improved isolation is provided with reference to FIGS. 1A-1C. An initial solution offered by the authors of the present disclosure in the '252 application is discussed with reference to FIGS. 2A-11F. A discussion of aspects of the present disclosure begins below with reference to FIG. 12A.

In this regard, FIGS. 1A-1C illustrate two components 100(1)-100(2) mounted on a substrate or laminate such as a printed circuit board (PCB) 102 separated by a distance d. While not shown explicitly, it should be appreciated that in most conventional packages, there is some form of mold compound encapsulating the components 100(1)-100(2). The components 100(1)-100(2) can be filters, acoustic or otherwise, SMDs, amplifiers (power amplifiers, low noise amplifiers, or the like), switches, chips containing integrated circuits, multiplexers, other elements, or combinations of these. The components 100(1)-100(2) may be part of a functional unit (e.g., a transceiver or transceiver chain) in a larger device such as a mobile terminal. The components 100(1)-100(2) may have electromagnetic emissions, which may induce currents or electrical fields in nearby components (i.e., crosstalk or EMI). In many cases, these induced currents are undesirable and may negatively impact the performance of the functional unit or larger device. In general, the closer the component 100(1) or 100(2) is to another component (either the other one of the components 100(1) or 100(2) or some other component not illustrated), the stronger the induced current. The easy solution is to spread the components 100(1)-100(2) apart by a large distance d. However, current commercial pressures, particularly for mobile communication devices, are to compress components 100(1)-100(2) on the PCB 102 to a small distance d and accept the crosstalk/EMI. That is, there is pressure for continuous miniaturization or shrinkage of absolute size of components with commensurate shrinkage of space between the components.

When design constraints force a small distance d, and the crosstalk/EMI exceeds acceptable limits, the typical approach is to use a shield made of conductive material placed between or around (e.g., a cage including a top shield) the individual components 100(1)-100(2). The most effective shields are those connected to a ground plane in the laminate as well as a top conductive shield. In some cases, the shield may be formed from bonded wire mesh. However, current assembly techniques are reaching a limit on how close components 100(1)-100(2) may be (i.e., how small distance d can be) because there is a minimum space between a component 100(1) and a shield, a minimum thickness of the shield, and another minimum space between the shield and the component 100(2). For example, using typical assembly processes, elements are generally at least eighty microns from one another. A bond-wire is typically sixty-five microns, so distance d is 225 microns (component to bond-wire (80)+thickness of bond-wire (65)+bond-wire to component (80) (80+65+80=225)). A full Faraday cage is heavy and makes assembly challenging as well as expensive.

Aspects of the present disclosure use a ferromagnetic material to form a thin isolation wall between components during packaging (as opposed to during assembly). While “thin” is a relative term, for the purposes of the present disclosure, thin means between five and fifty-five microns thick, and in an exemplary aspect, thin is less than approximately twenty-five microns, and in a specific aspect, less than or equal to approximately twenty microns, where approximately is a tolerance of five percent. The ferromagnetic material acts as an absorbing material rather than a shield and absorbs or at least reduces electromagnetic emissions from the components. More specifically, one or more absorbing isolation walls that form a box may be positioned between and/or around the components. The ferromagnetic material may be introduced during packaging, such as during the creation of an overmold, an undermold, or other mold material, and thus is not limited by the same space constraints of a conventional shield formed during assembly.

In this regard, FIGS. 2A-2C illustrate a pair of components 200(1)-200(2) on a substrate or laminate PCB 202 with a ferromagnetic isolation wall 204 positioned between them. In an exemplary aspect, an appropriate material for the isolation wall 204 is H5A, sold by the TDK Product Center (www.product.tdk.com). H5A is a manganese-zinc (Mn—Zn) ferrite material. This material is substantially cheaper than the gold or silver that is frequently used for electromagnetic shields. While H5A is specifically contemplated, other ferrite materials may be used in place thereof.

In an exemplary aspect, the isolation wall 204 extends from a top surface 206 of the PCB 202. In an alternate aspect, not shown, the isolation wall 204 extends down into the PCB 202 and may connect with a groundplane (also not shown) or other conductive metal layer in the PCB 202. Note that because the isolation wall 204 has a low conductivity, connection to such a groundplane does not turn the isolation wall 204 into an electromagnetic shield or make the isolation wall 204 an electrical extension of the groundplane.

In a further exemplary aspect, the isolation wall 204 may extend upwardly (away from the top surface 206 along the z-axis) to a top shield (not illustrated), which may be a conductive material rather than a ferromagnetic material. Note that this coupling to either the top surface 206 and/or the top shield is optional. Even when there is a physical connection between the isolation wall 204 and the top surface 206 or top shield, there is no practical electrical connection as the isolation wall 204 is generally non-conductive by virtue of its ferromagnetic nature.

In another exemplary aspect, instead of a single wall 204, the ferromagnetic material may be formed into a box as better illustrated in FIGS. 3A-3C, where the components 200(1)-200(2) are positioned within boxes 300(1)-300(2) respectively. The boxes 300(1)-300(2) may include five (5) sides (albeit with a shared wall), including a horizontal top 302 that extends in the x-y plane and four vertical walls 304(1)-304(4) that extend upwardly from the top surface 206 of the PCB 202 along the z-axis (with wall 304(1) being the shared wall). As with the isolation wall 204, the vertical walls 304(1)-304(4) may extend downwardly into the PCB 202 and may optionally be coupled to a groundplane or other metal layer within the PCB 202.

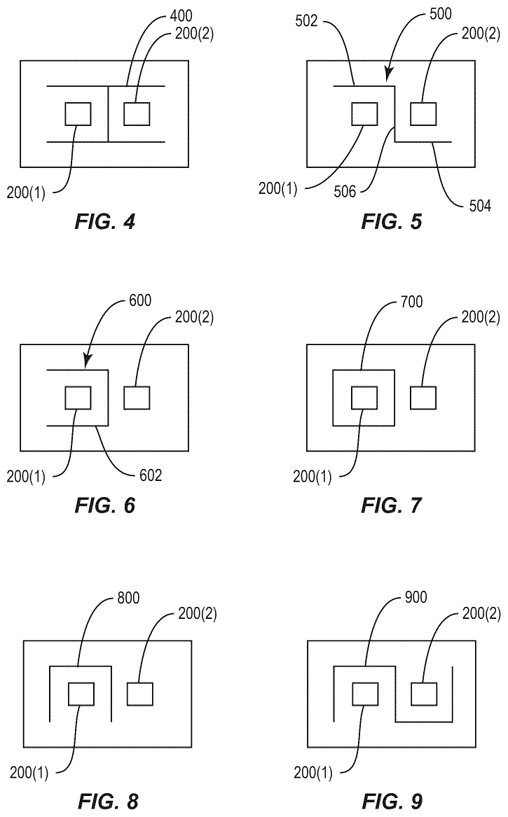

It should be appreciated that one or more isolation walls may be used to form an absorbing barrier between components. Likewise, the configuration of isolation walls may be varied without departing from the present disclosure. In this regard, FIGS. 4-9 illustrate some of the possible isolation wall arrangements, with the understanding that other arrangements, not specifically illustrated may also be used without departing from the present disclosure. FIG. 4, for example, illustrates a generally I- or H-shaped isolation wall 400 with isolation wall segments arranged in separate outwardly facing U-shaped locations where the components 200(1)-200(2) are located. FIG. 5 illustrates a generally reversed S-shaped isolation wall 500 that only has two lateral segments 502, 504 to accompany the shared isolation wall 506. A non-reversed S-shaped isolation wall is also contemplated. FIG. 6 illustrates a generally reversed C-shaped isolation wall 600 that has U-shaped chamber 602 around the component 200(1), but no isolation surrounding the component 200(2). Note that a non-reversed C-shaped isolation wall is also contemplated. FIG. 7 illustrates a topography where only one component 200(1) is contained within a box 700. FIG. 8 illustrates a generally n-shaped isolation wall 800 where only the component 200(1) has walls or segments on multiple sides. FIG. 9 illustrates a lazy-S isolation wall 900.

Note that in all the aspects illustrated in FIGS. 4-9 (as well as other variations discussed but not explicitly illustrated), there remains an isolation wall (or at least a segment of the isolation wall) between the components 200(1)-200(2) but spaced from both. It should be appreciated that other configurations for an isolation wall may be used without departing from the present disclosure, including an isolation wall with non-continuous segments but in each aspect, there would be at least one segment or isolation wall between the components. Likewise, while not explicitly illustrated, any of the aspects illustrated in FIGS. 4-9 may include a top shield because the top shield does not contribute to the required spacing between components.

Note further that while all the examples provided contemplate a shared isolation wall (e.g., wall 204 or 304(4)) between the two components 200(1)-200(2), the present disclosure is not so limited and instead, two isolation walls parallel to one another may be provided between the components. Note that this approach is more space-intensive but would provide greater isolation.

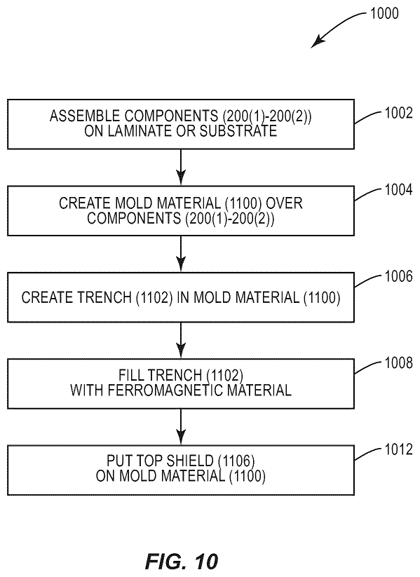

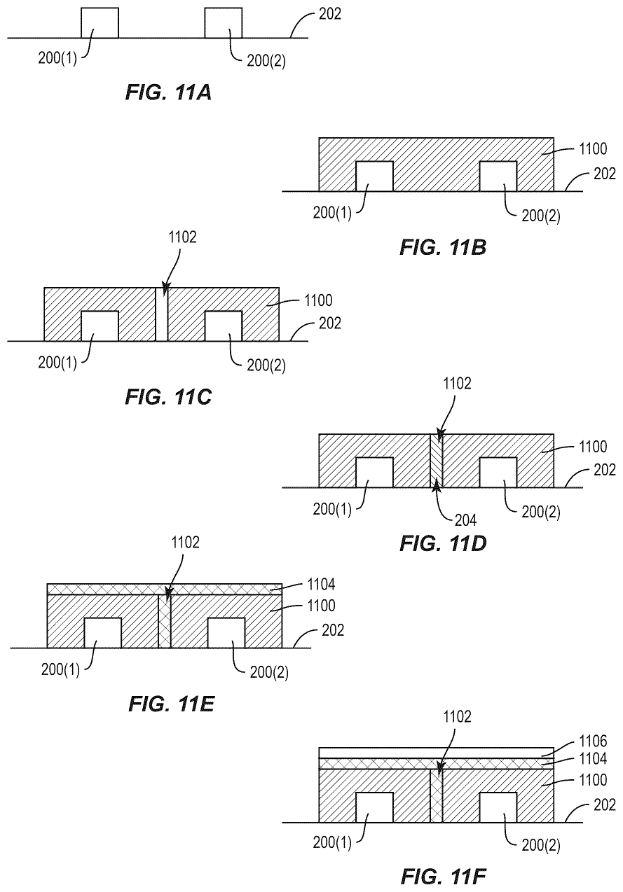

Against this backdrop, FIG. 10 illustrates a flowchart of a process 1000 for forming a package according to aspects of the present disclosure. FIGS. 11A-11F provide supporting illustrations of the various stages of the formation set forth in the process 1000. The process 1000 begins by assembling components 200(1)-200(2) on a laminate or substrate (block 1002, see FIG. 11A). Note that the laminate or substrate may be PCB 202. Further note that while the discussion has generally been presented in terms of just two components 200(1)-200(2), the present disclosure is readily extended to more than two components.

The process 1000 continues by creating an mold material 1100 over (also referred to herein as an overmold) the components 200(1)-200(2) (block 1004, see FIG. 11B). A trench 1102 is then formed in the mold material 1100 (block 1006, see FIG. 11C). The trench 1102 may be formed by milling or etching with a mask used to outline the portion to be etched, laser etching, or the like. While only a single isolation wall segment is shown, it should be appreciated that the trench 1102 so created may allow the creation of multiple wall segments. The trench 1102 is then filled with ferromagnetic material (block 1008, see FIG. 11D). Optionally, ferromagnetic material 1104 may be positioned on top of the mold material 1100 (see FIG. 11E) A top shield 1106 is then formed over the overmold 1100 (and if present over the ferromagnetic material 1104) (block 1012, see FIG. 11F).

Note while the above discussion specifically contemplates an overmold, it should be appreciated that the steps are readily modified for an undermold (e.g., a die side structure). Accordingly, as used herein a “mold material” contemplates both over and undermold structures. That is, the present disclosure specifically contemplates using an isolation wall between components regardless of on which “side” of the laminate the components are positioned (e.g., top side, back side, both sides, or what have you). Thus, components on a back side of a laminate as may occur in DSBGA or DSLGA packages may benefit from aspects of the present disclosure.

Note further, there may be situations where the isolation wall is preconstructed and such structure is deposited or assembled in place before application of the mold material.

Note that while all of the structures illustrated herein are generally rectilinear, the present disclosure is not so limited, and a honeycomb-like structure or other polygons and spline-like could be used (e.g., pentagons, hexagons, octagons, or the like).

While the above aspects describe vertical absorbing walls which help mitigate EMI and crosstalk, the present disclosure is not limited to just these vertical walls. Rather, aspects of the present disclosure contemplate putting an absorbing wall or layer parallel to and “above” a plane holding components. Further, this absorbing layer may be positioned between the components and a conductive layer that acts as a shield layer. As such, this absorbing layer may be done late in the assembly process thereby simplifying the manufacturing process for the package.

In this regard, FIG. 12A is a cross-sectional side elevation of a package 1200 with a laminate 1202 (sometimes referred to as a metallization structure). One or more metal layers 1204(1)-1204(B) may be within the laminate 1202. The laminate 1202 may have a top surface 1206 on which components 200(1), 200(2) may be positioned. The top surface 1206 is generally planar and lies in an x-y plane. An overmold material 1208 may be positioned over the components 200(1), 200(2) and the laminate 1202. An absorbing layer 1210 may be positioned over the overmold material 1208. As described above, the absorbing layer 1210 may be a ferromagnetic material. The absorbing layer 1210 may be planar. A conductive shield 1212 may be positioned over the absorbing layer 1210. It is also possible that another mold material may be placed between the absorbing layer 1210 and the conductive shield 1212. This approach may be used where it is difficult to adhere the conductive shield 1212 to the absorbing layer 1210, or according to processing requirements, electric isolation, or the like.

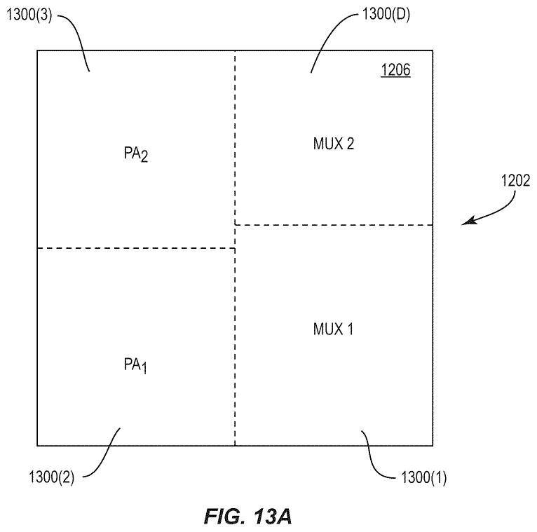

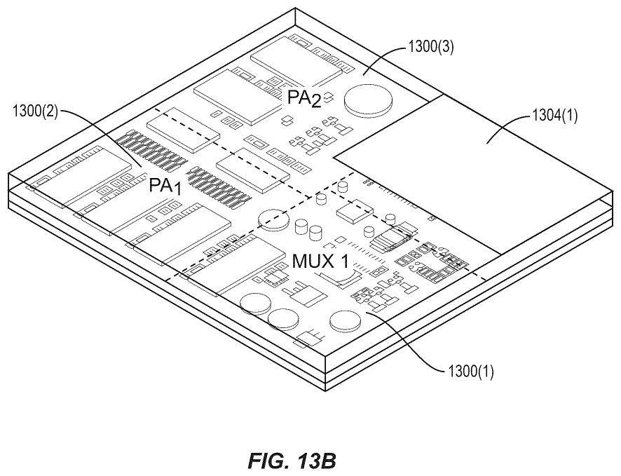

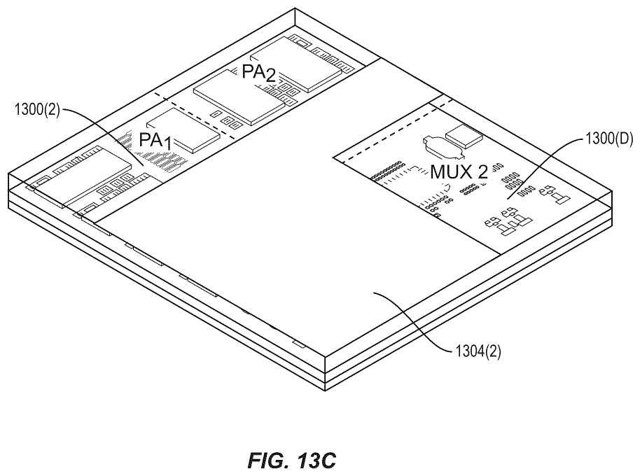

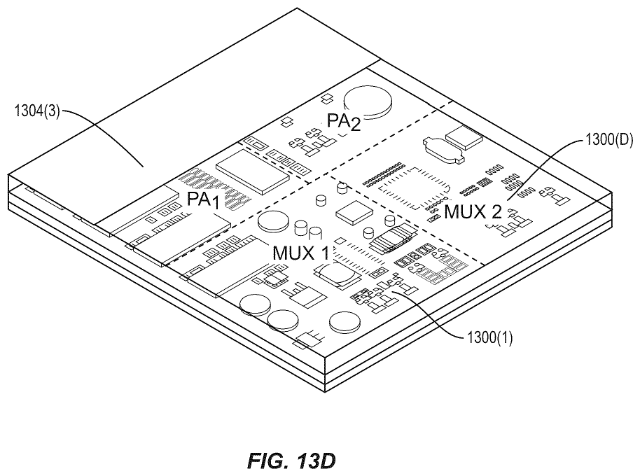

As better illustrated in FIG. 12B, the absorbing layer 1210 may be coextensive with the x-y dimensions of the package 1200. However, as shown in FIGS. 13A-13D, the present disclosure contemplates partial planes that cover only a portion of the top surface 1206 of the laminate 1202.

More particularly, as shown in FIG. 13A, the top surface 1206 may have zones 1300(1)-1300(D). Exemplary zones 1300(1)-1300(D) include multiplexer zone 1300(1), power amplifier zone 1300(2), or the like. These zones 1300(1)-1300(D) may have differing emissions and thus may need different amounts of attenuation/absorption to meet design criteria. Accordingly, as illustrated in FIGS. 13B-13D, different zones 1300(1)-1300(D) may have partial absorbing layers 1304(1)-1304(3) that cover different ones of the zones instead of covering the entire plane. Note also that while not illustrated, there may be different discontinuous partial absorbing layers that still cover less than 100% of the total laminate (e.g., it could cover zones 1300(1) and 1300(D). Alternatively, the partial absorbing layers may cover elements based on function (e.g., an inductor radiates more than some other element for some reason and accordingly, the inductor is covered with a top absorbing wall). Note that this absorption based on function may also be extended to the vertical walls (e.g., surrounding an area of the die based on function).

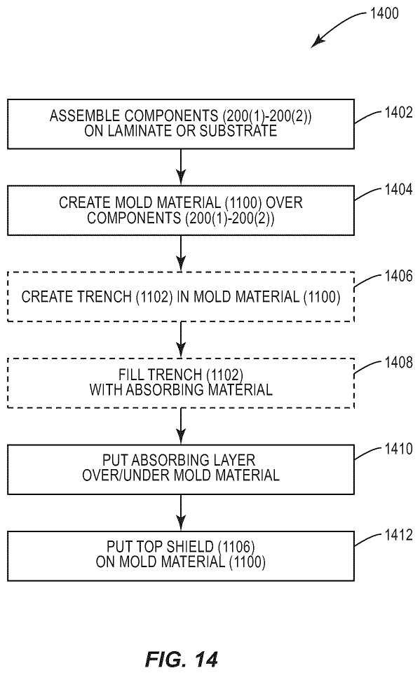

FIG. 14 illustrates a process 1400, similar to process 1000, for forming a package with an absorbing layer 1210 (or partial absorbing layers 1304) thereon. The process 1400 by assembling components 200(1)-200(2) on a laminate or substrate (block 1402). Note that the laminate or substrate may be PCB 202 or laminate 1202. Further note that while the discussion has generally been presented in terms of just two components 200(1)-200(2), the present disclosure is readily extended to more than two components as well as elements embedded in the laminate 1202.

The process 1400 continues by creating an overmold 1100 over the components 200(1)-200(2) (block 1404). Optionally, in keeping with the authors' previous teachings, a trench 1102 is then formed in the overmold 1100 (block 1406). The trench 1102 may be formed by milling or etching with a mask used to outline the portion to be etched, laser etching, or the like. The trench 1102 is then filled with absorbing material (block 1408).

The process 1400 continues by putting an absorbing layer over the overmold material (block 1410) (or under if this is an undermold situation). A top shield 1106 is then formed over the overmold 1100 (block 1412).

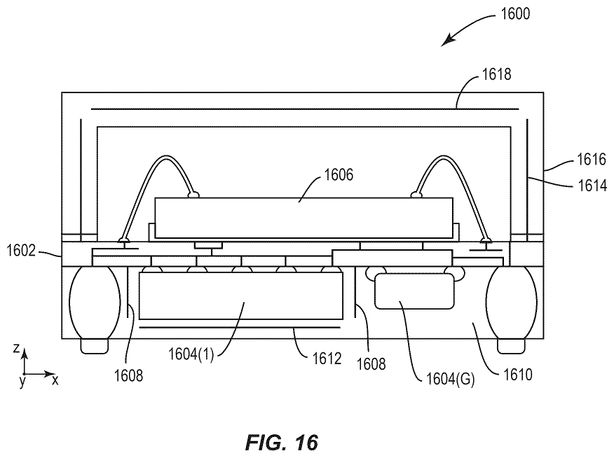

Note while the above discussion specifically contemplates an overmold, it should be appreciated that the steps are readily modified for an undermold (e.g., a die side structure). Accordingly, as used herein, a “mold material” contemplates both over and undermold structures. Likewise, the use of an absorbing layer is not limited to a top side of the package. For example, in a DSBGA, there may be absorbing layers over a first die on a first side and below a second die on a second side, as better illustrated in FIG. 16.

In this regard, FIG. 16 illustrates a double-sided package 1600. The double-sided package includes an internal metallization layer 1602 with components 1604(1)-1604(G) on the first side of the metallization layer 1602. Other dies or components 1606 are positioned on a second side of the metallization layer 1602. Vertical (in the z-axis direction perpendicular to the metallization layer 1602) absorbing walls 1608 are positioned around the component 1604(1) in mold material 1610. An additional top absorbing wall 1612 is positioned “below” the component 1604(1) but also in the mold material 1610. Similarly, side absorbing walls 1614 are positioned in mold material 1616 on the other side of the metallization layer 1602 around the die 1606. A top absorbing wall 1618 may be positioned above the die 1606 in the mold material 1616. While not shown, there may be an absorbing wall in the metallization layer 1602.

Note also that the absorbing layer 1210 (or partial layers) may be used with or without the absorbing isolation walls of the earlier discussion. Further, the absorbing layer may be coupled to the isolation walls, but such is not required. Note also that the absorbing layer can also be used in combination with wire-bonds, or other bulky and expensive Faraday type cages. While reducing reliance on these features is a net design positive in terms of cost and space savings, there may be situations where the combination of features is warranted.

While the discussion of package 1200 describes things in terms “above,” “over,” or “top,” it should be appreciated that these are relative terms and more specifically these elements may be positioned relative to one another on a z-axis.

The systems and methods for component isolation, according to aspects disclosed herein, may be provided in or integrated into any processor-based device. Examples, without limitation, include a base station, small cell station, set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

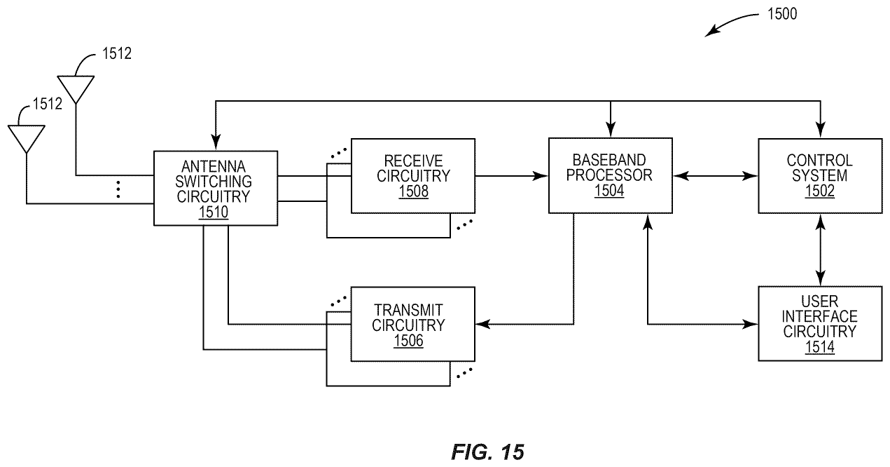

With reference to FIG. 15, the concepts described above may be implemented in various types of user elements 1500, such as mobile terminals, smart watches, tablets, computers, navigation devices, access points, and like wireless communication devices that support wireless communications, such as cellular, wireless local area network (WLAN), Bluetooth, and near field communications. The user elements 1500 will generally include a control system 1502, a baseband processor 1504, transmit circuitry 1506, receive circuitry 1508, antenna switching circuitry 1510, multiple antennas 1512, and user interface circuitry 1514. In a non-limiting example, the control system 1502 can be a field-programmable gate array (FPGA) or an application-specific integrated circuit (ASIC), as an example. In this regard, the control system 1502 can include at least a microprocessor(s), an embedded memory circuit(s), and a communication bus interface(s). The receive circuitry 1508 receives radio frequency signals via the antennas 1512 and through the antenna switching circuitry 1510 from one or more base stations. A low noise amplifier and a filter of the receive circuitry 1508 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1504 processes the digitized received signal to extract the information or data bits conveyed in the received signal. This processing typically comprises demodulation, decoding, and error correction operations. The baseband processor 1504 is generally implemented in one or more digital signal processors (DSPs) and ASICs.

For transmission, the baseband processor 1504 receives digitized data, which may represent voice, data, or control information, from the control system 1502, which it encodes for transmission. The encoded data is output to the transmit circuitry 1506, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1512 through the antenna switching circuitry 1510 to the antennas 1512. The multiple antennas 1512 and the replicated transmit and receive circuitries 1506, 1508 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
a laminate;
a first component positioned on the laminate;
a conductive shield; and
at least one absorbing layer positioned between the first component and the conductive shield.

2. The package of claim 1, wherein the laminate comprises a planar top surface and the first component is positioned on the planar top surface, and the at least one absorbing layer is parallel to and above the planar top surface.

3. The package of claim 1, further comprising a mold material covering the first component and on which the at least one absorbing layer is positioned.

4. The package of claim 1, wherein the at least one absorbing layer covers less than 100% of the laminate.

5. The package of claim 1, further comprising an absorbing isolation wall extending up from the laminate towards the at least one absorbing layer.

6. The package of claim 1, wherein the at least one absorbing layer has a thickness between five and fifty microns.

7. The package of claim 6, wherein the thickness is approximately twenty microns.

8. The package of claim 1, wherein the at least one absorbing layer comprises H5A material.

9. The package of claim 1, wherein the at least one absorbing layer comprises manganese-zinc material.

10. The package of claim 1, wherein the at least one absorbing layer comprises a ferromagnetic material.

11. The package of claim 1, wherein the laminate comprises a printed circuit board.

12. The package of claim 1, wherein the first component is selected from the group consisting of: an amplifier, a surface-mounted device, a multiplexer, a filter, and a chip.

13. The package of claim 1 integrated into a device selected from the group consisting of: base station, a small-cell station, a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

14. The package of claim 1 integrated into a communication device, the communication device comprising:
a transceiver chain comprising the package.

15. A method of forming a package, comprising:
placing a component on a laminate;
placing mold material over the component;
placing an absorbing layer over the overmold material; and
placing a conductive shield over the absorbing layer.

16. The method of claim 15, further comprising placing a second component on the laminate and forming a trench between the component and the second component.

17. The method of claim 16, further comprising forming a box of ferromagnetic material around the component.

18. The method of claim 17, further comprising filling the trench with the box of ferromagnetic material.

19. The method of claim 15, wherein placing the absorbing layer comprises placing a ferromagnetic absorbing material.

20. A package comprising:
a laminate;
a first component positioned on a first side of the laminate;
wherein the laminate comprises a second side of the laminate opposite the first side; and
at least one absorbing layer positioned in an undermold on the second side of the laminate.
